(19) United States
(12) Patent Application Publication
(10) Pub. No.: US 2026/0052826 A1
(43) Pub. Date: Feb. 19, 2026

(54) LIGHT EMITTING DEVICE

(71) Applicant: SEOUL SEMICONDUCTOR CO., LTD., Ansan-si (KR)

(72) Inventor: Jung Hun SON, Ansan-si (KR)

(21) Appl. No.: 19/296,022

(22) Filed: Aug. 11, 2025

Related U.S. Application Data
(60) Provisional application No. 63/683,133, filed on Aug. 14, 2024.

(51) Int. Cl. H10H 29/85; H10H 29/24; H10H 29/856

(52) U.S. Cl. CPC H10H 29/857; H10H 29/24; H10H 29/856

(57) ABSTRACT

Provided is a light emitting device including: a substrate unit that includes a light emitting substrate; a plurality of first light emitters that are arranged in a first direction on the light emitting substrate to generate light; and a plurality of second light emitters that are arranged in the first direction on the light emitting substrate to generate the light. The plurality of first light emitters and the plurality of second light emitters are disposed in a second direction perpendicular to the first direction, and a size of each of the plurality of first light emitters is larger than a size of each of the plurality of second light emitters in a plan view.

### CROSS REFERENCE TO RELATED APPLICATION

This application claims priority from and the benefit of U.S. Provisional Patent Application No. 63/683,133, filed on Aug. 14, 2024, which is hereby incorporated by reference for all purposes as if fully set forth herein.

### BACKGROUND

### Field

Embodiments of the invention relate generally to a light emitting device.

### Discussion of the Background

A light emitting device is a device that generates light. Recently, a light emitting device is used in various fields such as display devices, automobile lamps, and general lighting. In general, a light emitting device for a vehicle is installed at the front end portion of a vehicle and irradiates light forward, thereby helping a driver secure visibility. This light emitting device may include a plurality of light emitters that generate light to form a low beam pattern and a high beam pattern according to a driver's manipulation. For example, the light emitting device should be capable of irradiating an appropriate amount of light over an appropriate range to fulfill the respective purposes of the low beam pattern and the high beam pattern.

However, the sizes of the light emitters in the conventional light emitting device are identically formed, making it difficult to generate an appropriate amount of light suitable for the intended purpose.

The above information disclosed in this Background section is only for understanding of the background of the inventive concepts, and, therefore, it may contain information that does not constitute prior art.

### SUMMARY

Embodiments of the invention provide a light emitting device that is small in size and capable of generating an appropriate amount of light suitable for its intended purpose.

Embodiments of the invention also provide a light emitting device capable of generating light that may form a low beam pattern and a high beam pattern.

Embodiments of the invention further provide a light emitting device that may form various beam patterns.

Embodiments of the invention also provide a light emitting device capable of efficiently emitting light by increasing light extraction efficiency.

Embodiments of the invention also provide a light emitting device capable of efficiently emitting heat to increase heat dissipation efficiency and improve reliability.

Additional features of the inventive concepts will be set forth in the description which follows, and in part will be apparent from the description, or may be learned by practice of the inventive concepts.

In accordance with one aspect of the invention, there may be provided a light emitting device, including: a substrate unit that includes a light emitting substrate; a plurality of first light emitters that are arranged in a first direction on the light emitting substrate to generate light; and a plurality of second light emitters that are arranged in the first direction on the light emitting substrate to generate the light, wherein the plurality of first light emitters and the plurality of second light emitters are disposed in a second direction perpendicular to the first direction, and a size of each of the plurality of first light emitters is larger than a size of each of the plurality of second light emitters in a plan view.

Further, there may be provided the light emitting device in which a ratio of a length of the second light emitter in the second direction to a length of the second light emitter in the first direction is smaller than a ratio of a length of the first light emitter in the second direction to a length of the first light emitter in the first direction.

Further, there may be provided the light emitting device in which a sum of areas of the plurality of first light emitters is larger than twice of a sum of areas of the plurality of second light emitters.

Further, there may be provided the light emitting device in which a length of the first light emitter in the first direction is smaller than a length of the second light emitter in the second direction, and a length of the first light emitter in the second direction is larger than a length of the second light emitter in the first direction.

Further, there may be provided the light emitting device further including: a reflective layer that is disposed on the light emitting substrate and reflects the light generated from the plurality of first light emitters and the plurality of second light emitters.

Further, there may be provided the light emitting device in which the reflective layer covers circumferential surfaces of the plurality of first light emitters and circumferential surfaces of the plurality of second light emitters.

Further, there may be provided a light emitting device, including: a substrate unit including a light emitting substrate; a plurality of first light emitters that are arranged and supported in a first direction on the light emitting substrate to generate light; and a plurality of second light emitters that are arranged and supported in the first direction on the light emitting substrate to generate the light, wherein the light emitting substrate includes: a first region in which the plurality of first light emitters are arranged; and a second region in which the plurality of second light emitters are arranged, and a length of the first region in the first direction is smaller than a length of the second region in the first direction.

Further, there may be provided the light emitting device in which a separation distance from one side of the first region to one side of the light emitting substrate is larger than a separation distance from one side of the second region to one side of the light emitting substrate.

Further, there may be provided the light emitting device in which the plurality of first light emitters includes: a plurality of first upper devices; and a plurality of second upper devices that are spaced further apart from the second light emitter than the plurality of first upper devices, and the first region includes: a first upper device region in which the plurality of first upper devices are arranged; and a second upper device region in which the plurality of second upper devices are arranged, and a length of the first upper device region in the first direction is larger than a length of the second upper device region in the first direction.

Further, there may be provided the light emitting device in which the second upper device region is disposed on an inner side of the first upper device region when projected toward the first upper device region.

Further, there may be provided a light emitting device, including: a substrate unit; a plurality of first light emitters that are arranged and supported on the substrate unit in a first direction to generate light; a plurality of second light emitters that are arranged and supported on the substrate unit in the first direction to generate the light; and a plurality of pads that are arranged and supported on the substrate unit in the first direction and are electrically connected to the plurality of first light emitters and the plurality of second light emitters, wherein the substrate unit includes: a light emitting substrate that supports the plurality of first light emitters and the second light emitters; and a pad substrate that supports the plurality of pads and the light emitting substrate, and the light emitting substrate protrudes upward from the pad substrate so that a surface of the light emitting substrate is disposed above a surface of the pad substrate.

Further, there may be provided the light emitting device in which a length of the light emitting substrate in a vertical direction is larger than a length of the pad substrate in the vertical direction.

Further, there may be provided the light emitting device in which the plurality of pads include: a plurality of first pads that are electrically connected to the plurality of first light emitters while being spaced apart from each other; and a plurality of second pads that are supported on the pad substrate while being spaced apart from each other, and electrically connected to the plurality of second light emitters, and the light emitting substrate is disposed between the plurality of first pads and the plurality of second pads.

Further, there may be provided the light emitting device in which a number of second pads is different from a number of first pads.

Further, there may be provided the light emitting device in which a separation distance between the plurality of pads is larger than a separation distance between the plurality of first light emitters and a separation distance between the plurality of second light emitters. Further, there may be provided the light emitting device in which the plurality of

first pads include: a plurality of first upper pads that are spaced apart from each other in the first direction; and a plurality of second upper pads that are spaced apart from each other in the first direction, but spaced further apart from the light emitting substrate than the plurality of first upper pads, and wherein at least some of the plurality of first upper pads are disposed to overlap the plurality of second upper pads disposed adjacent to each other when projected in a second direction perpendicular to the first direction.

Further, there may be provided the light emitting device in which the plurality of second pads include: a plurality of first lower pads that are spaced apart from each other in the first direction; and a plurality of second lower pads that are spaced apart from each other in the first direction, but disposed between the plurality of first lower pads and the light emitting substrate, and wherein at least some of the plurality of second lower pads are disposed to overlap the plurality of first lower pads disposed adjacent to each other when projected in a second direction perpendicular to the first direction.

Further, there may be provided the light emitting device, further including: a heat sink that supports the pad substrate and dissipates heat from the pad substrate.

Further, there may be provided the light emitting device, further including: a plurality of controllers that are electrically connected to the plurality of pads for controlling the plurality of first light emitters and the plurality of second light emitters; and a plurality of bonding parts that electrically connect the plurality of controllers and the plurality of pads.

Further, there may be provided the light emitting device in which at least one of one side of the plurality of bonding parts and the other side opposite the one side of the plurality of bonding parts is formed to be convex upward.

The light emitting device according to the embodiments of the invention may be small in size and generate light of an appropriate amount of light suitable for the purpose.

In addition, the light emitting device may generate light to form one or more patterns.

According to the embodiments of the invention, by increasing the light extraction efficiency of the light emitting device, it is possible to efficiently emit light.

According to the embodiments of the invention, it is possible to delicately control the light emitting region.

According to the embodiments of the invention, by efficiently emitting heat, it is possible to increase the heat dissipation efficiency and improve the reliability.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the inventive concepts and are incorporated in and constitute a part of this disclosure, illustrate embodiments, and together with the description serve to explain the inventive concepts.

FIG. 1 is a schematic perspective view of a light emitting device according to one embodiment of the invention.

FIG. 2 is a schematic cross-sectional view of the light emitting device of FIG. 1 taken along line A-A′.

FIG. 3 is a schematic diagram illustrating a first light emitter and a second light emitter of the light emitting device of FIG. 1.

FIG. 4 is a schematic plan view illustrating a plurality of first light emitters, a plurality of second light emitters, and a plurality of pads of the light emitting device according to one embodiment of the invention.

FIG. 5 is an enlarged schematic view of part B of FIG. 4.

FIG. 6 is a schematic graph illustrating a deviation of luminance of the light emitting device according to one embodiment of the invention.

FIG. 7 is a schematic diagram illustrating an appearance in which the plurality of first light emitters and the plurality of second light emitters of the light emitting device according to one embodiment of the invention are electrically connected to the plurality of pads.

FIG. 8 is a schematic diagram illustrating an appearance in which a bonding part is disposed on the pad of the light emitting device according to one embodiment of the invention.

FIG. 9 is a schematic cross-sectional view of the bonding part of FIG. 8 taken along line B-B′.

FIG. 10 is a schematic cross sectional view of a light emitting device according to another embodiment of the invention.

FIG. 11 is a schematic plan view showing a plurality of first light emitters, a plurality of second light emitters, and a plurality of pads of the light emitting device according to the second embodiment of the invention.

FIG. 12 is a schematic plan view of a substrate unit of a light emitting device according to another embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this disclosure, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a specific configuration of a light emitting device 1 according to an embodiment of the invention will be described with reference to the drawings.

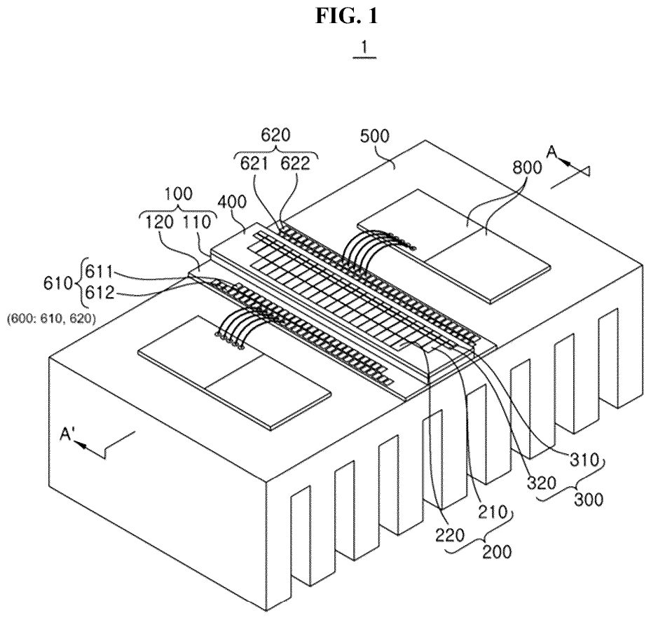

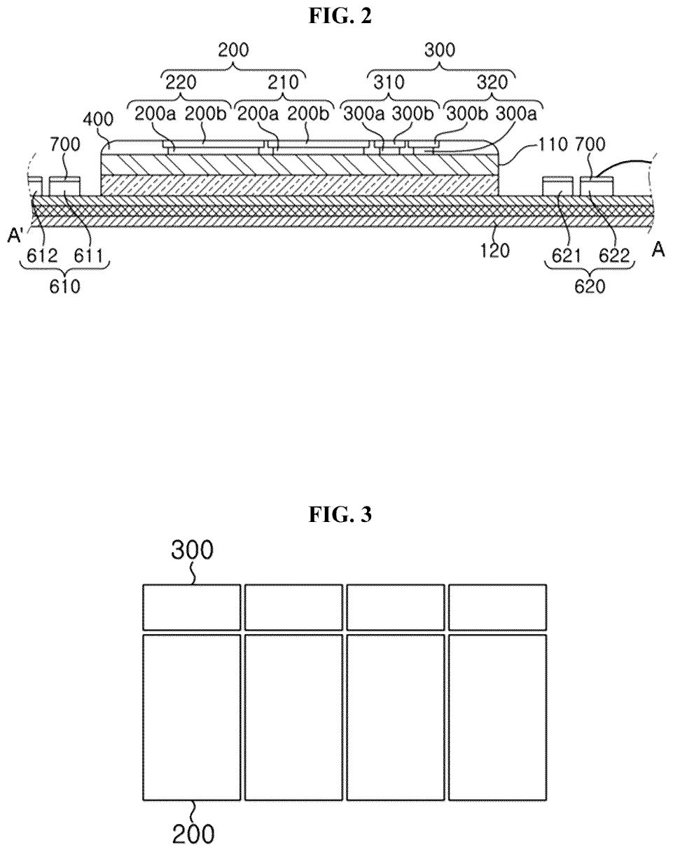

FIG. 1 is a schematic perspective view of a light emitting device according to one embodiment of the invention, FIG. 2 is a schematic cross-sectional view of the light emitting device of FIG. 1 taken along line A-A′, and FIG. 3 is a schematic diagram illustrating a first light emitter and a second light emitter of the light emitting device of FIG. 1.

Referring to FIGS. 1, 2, and 3, the light emitting device 1 may be a device that receives power from the outside and generates light. The light emitting device 1 may be applied to a vehicle headlamp, but is not limited thereto. In other words, the light emitting device 1 may generate light toward a lens of a vehicle lamp disposed in front to form one or more patterns. The pattern may be a high beam pattern, a low beam pattern, a changeable pattern, etc. The light emitting device 1 may include a substrate unit 100, a first light emitter 200, a second light emitter 300, a reflective layer 400, a heat sink 500, a pad 600, a bonding part 700, and a controller 800.

The substrate unit 100 may support the first light emitter 200, the second light emitter 300, and the pad 600. For example, the substrate unit 100 may be a printed circuit board (PCB), a ceramic substrate, a conductive substrate, etc. In addition, the substrate unit 100 may include an alloy composed of one or more of Cu, Zn, Au, Ni, Al, Mg, Cd, Be, W, Mo, Si, Ag, and Fe, or a part of these. However, this is merely an example, and the substrate unit 100 may also include one or more of FR1, CEM-1, and FR-4. For example, the FR1 may be a material in which copper foil and laminated paper are laminated, and the CEM-1 may be a material in which copper foil, glass fiber fabric, laminated paper, and glass fiber fabric are sequentially laminated. In addition, the FR-4 may be a material in which copper foil and glass fiber textile or glass fiber fabric is laminated. In addition, the substrate unit 100 may include ceramics such as alumina (Al₂O₃), aluminum nitride (AIN), and zirconia toughened alumina (ZTA). In addition, the substrate unit 100 may include a light emitting substrate 110 and a pad substrate 120.

The light emitting substrate 110 may support a first light emitter 200 and a second light emitter 300. In other words, one or more first light emitters 200 and one or more second light emitters 300 may be disposed on an upper surface of the light emitting substrate 110. Meanwhile, sizes of one or more first light emitters 200 and one or more second light emitters 300 disposed on the upper surface of the light emitting substrate 110 may be differently formed from each other. In other words, the size of the first light emitter 200 may be formed to be larger than the size of the second light emitter 300. For example, the sum of areas of the plurality of first light emitters 200 may be formed to be larger than twice of the sum of areas of the plurality of second light emitters 300. The first light emitter 200 may include at least one first array in which the plurality of light emitters extend in a first direction, and the second light emitter 300 may include at least one second array in which the plurality of light emitters extend in the first direction, and the first array of the first light emitter 200 and the second array of the second light emitter 300 may be disposed in parallel. The first light emitter 200 and the second light emitter 300 may be arranged in a second direction perpendicular to the first direction. The number of light emitters included in the first array of the first light emitters 200 extending in the first direction may be equal to the number of light emitters included in the second array of the second light emitters 300 extending in the first direction. Therefore, a high amount of light may be secured.

In addition, the light emitting substrate 110 may be disposed on the pad substrate 120. When the light emitting substrate 110 is disposed on an upper surface of the pad substrate 120, the light emitting substrate 110 may be interposed between a first pad 610 and a second pad 620 to be described below. In addition, the light emitting substrate 110 may be spaced apart from the first pad 610 and the second pad 620 in a plan view.

The light emitting substrate 110 may be protruded upward from a surface of the pad substrate 120 so that the upper surface of the light emitting substrate 110 is disposed above the upper surface of the pad substrate 120. Meanwhile, although the light emitting substrate 110 is described as being disposed on an upper side of the pad substrate 120 in this disclosure, when the light emitting device 1 is mounted on the vehicle lamp, the light emitting substrate 110 may be disposed in front of the pad substrate 120.

The light emitting substrate 110 may be formed to be smaller than the pad substrate 120. In a plan view, at least a portion of an edge of the light emitting substrate 110 may be disposed on an inner side of an edge of the pad substrate 120. The light emitting substrate 110 may be, but is not limited to, a ceramic substrate such as alumina (Al₂O₃), aluminum nitride (AlN), and zirconia toughened alumina (ZTA), FR1, CEM-1, FR-4, a printed circuit board (PCB), or a conductive substrate.

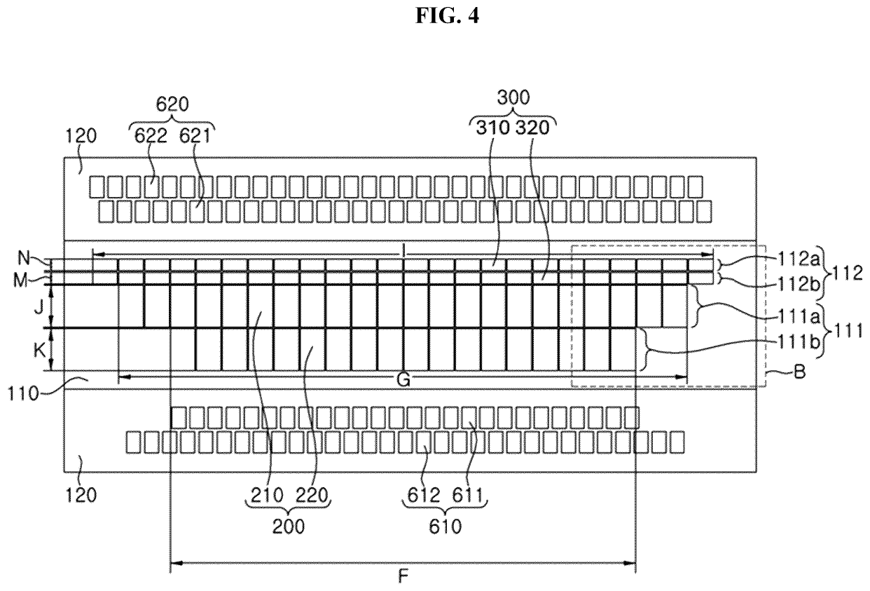

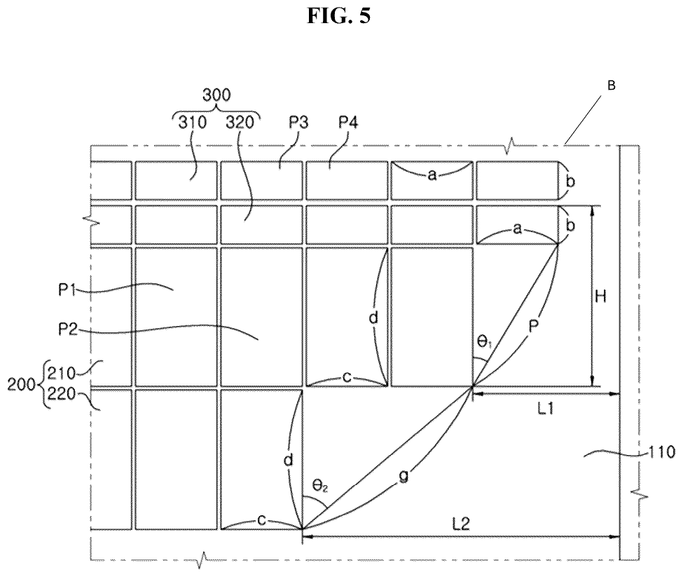

FIG. 4 is a schematic plan view illustrating a plurality of first light emitters, a plurality of second light emitters, and a plurality of pads of the light emitting device according to one embodiment of the invention, and FIG. 5 is an enlarged schematic view of part B of FIG. 4.

Referring further to FIGS. 4 and 5, a length of the light emitting substrate 110 in the first direction (horizontal direction in FIG. 4) may be formed to be larger than a length in the second direction (vertical direction in FIG. 4) perpendicular to the first direction. A first region 111 and a second region 112 of the light emitting substrate 110 may be formed in the light emitting substrate 110.

The first region 111 may be a region in which the plurality of first light emitters 200 are disposed. A first length of the first region 111 in the first direction may be a length from one side of the first light emitter 200 adjacent to one side of the light emitting substrate 110 among the plurality of first light emitters 200 to the other side of the first light emitter 200 disposed adjacent to the other side of the light emitting substrate 110. The length of the first region 111 may be smaller than a second length of the second region 112 in the first direction.

A separation distance from one side of the first region 111 to a side surface (edge) of the light emitting substrate 110 with respect to the first direction may be larger than a length from one side of the second region 112 to the side surface (edge) of the light emitting substrate 110. In addition, the first region 111 may be disposed so that, when projected toward the second region 112, both sides of the first region 111 are disposed on an inner side of both sides of the second region 112.

In addition, the first region 111 may include a plurality of upper device regions 111a and 111b. The plurality of upper device regions 111a and 111b may be arranged in the second direction. The plurality of upper device regions 111a and 111b may include a first upper device region 111a and a second upper device region 111b.

The first upper device region 111a may be a region in which a plurality of first upper devices 210 are disposed. The first upper device region 111a may be located between the second upper device region 111b and the second light emitter 300. A length G of the first upper device region 111a in the first direction may be a length from one side of the first upper device 210 disposed adjacent to one side of the light emitting substrate 110 among the plurality of first upper devices 210 to the other side of the first upper device 210 disposed adjacent to the other side of the light emitting substrate 110. The length G of the first upper device region 111a in the first direction may be larger than a length F of the second upper device region 111b in the first direction. In addition, a length J of the first upper device region 111a in the second direction may be substantially equal to a length d of the first upper device 210 in the second direction, a length K of the second upper device region 111b in the second direction, and a length d of the second upper device 220 in the second direction.

The second upper device region 111b may be a region in which a plurality of second upper devices 220 are disposed. The second upper device region 111b may be disposed further away from the second light emitter 300 than the first upper device region 111a in the second direction (i.e., vertical direction). A length F of the second upper device region 111b in the first direction may be the length from one side of the second upper device 220 adjacent to one side of the light emitting substrate 110 among the plurality of second upper devices 220 to the other side of the second upper device 220 disposed adjacent to the other side of the light emitting substrate 110. When the second upper device region 111b is projected toward the first upper device region 111a, the second upper device region 111b may be disposed on an inner side of the first upper device region 111a. In other words, when the second upper device region 111b is projected toward the first upper device region 111a, both ends of the second upper device region 111b may be disposed on an inner side of both ends of the first upper device region 111a. A length K of the second upper device region 111b in the second direction may be equal to the length d of the second upper device 220 in the second direction.

The second region 112 may be a region in which the plurality of second light emitters 300 are disposed. A length of the second region 112 in the first direction may be a length from one side of the second light emitter 300 adjacent to one side of the light emitting substrate 110 among the plurality of second light emitters 300 to the other side of the second light emitter 300 disposed adjacent to the other side of the light emitting substrate 110. An area of the second region 112 may be smaller than an area of the first region 111.

The second region 112 may include a plurality of lower device regions. The plurality of lower device regions may be arranged in the second direction. The plurality of lower device regions may include a first lower device region 112a and a second lower device region 112b.

The first lower device region 112a may be a region in which a plurality of first lower devices 310 are disposed. The first lower device region 112a may be disposed further away from the first light emitter 200 than the second lower device region 112b in the second direction (i.e., vertical direction). A length I of the first lower device region 112a in the first direction may be a length from one side of the first lower device 310 disposed adjacent to one side of the light emitting substrate 110 among the plurality of first lower devices 310 to the other side of the first lower device 310 disposed adjacent to the other side of the light emitting substrate 110. The length I of the first lower device region 112a in the first direction may be equal to a length I of the second lower device region 112b in the first direction. In addition, a length N of the first lower device region 112a in the second direction may be equal to a length M of the second lower device region 112b in the second direction. The length N of the first lower device region 112a in the second direction may be smaller than the length J of the first upper device region 111a in the second direction or the length K of the second upper device region 111b in the second direction.

Meanwhile, the first upper device region 111a and the second lower device region 112b may be expressed as in the following Mathematical Expression 1.

$$I - G > H \qquad [ Mathematical Expression 1 ]$$

In the above Mathematical Expression 1, with respect to the second direction, “H” denotes a length H from one side (lower side of the first upper device region 111a in FIG. 5) of an edge of the first upper device region 111a disposed opposite the second upper device region 111b to the other side (upper side of the second lower device region 112b in FIG. 5) of an edge of the second lower device region 112b disposed opposite the first lower device region 112a. In other words, “H” may be a maximum distance in the second direction from one surface of the upper device region 111a disposed closest to the second region 112 among the plurality of upper device regions to one surface of the first lower device region 112a disposed closest to the first region 111 among the plurality of lower device regions. “I” denotes a length I of the second lower device region 112b in the first direction, and “G” denotes a length G of the first upper device region 111a in the first direction. Therefore, when the light emitting device 1 is turned on, a shape in which a light pattern gradually narrows or widens may be implemented.

The pad substrate 120 may support the light emitting substrate 110 and the plurality of pads 600 which includes a first pad 610 and a second pad 620. When the heat sink 500 is additionally disposed, the pad substrate 120 may be disposed between the light emitting substrate 110 and the heat sink 500. In other words, the light emitting substrate 110, the first pad 610, and the second pad 620 may be disposed on one side of the pad substrate 120. The heat sink 500 may be disposed under the pad substrate 120.

In a plan view, an area of the pad substrate 120 may be larger than an area of the light emitting substrate 110. In other words, in a plan view, the edge of the light emitting substrate 110 may be disposed on the inner side of the edge of the pad substrate 120. In addition, the area of the pad substrate 120 may be smaller than an area of the heat sink 500. In other words, in a plan view, the edge of the pad substrate 120 may be disposed on an inner side of an edge of the heat sink 500. In addition, the length of the pad substrate 120 in the first direction may be larger than the length of the light emitting substrate 110 in the first direction. The pad substrate 120 may be a ceramic substrate such as alumina (Al₂O₃), aluminum nitride (AlN), or zirconia toughened alumina (ZTA), but is not limited thereto.

The first light emitter 200 may be disposed on the light emitting substrate 110 to generate light. When the first light emitter 200 is mounted on the lamp, the first light emitter 200 may be disposed under the second light emitter 300, and light may be flipped upside down or refracted upward while transmitting a lens of a lamp. The first light emitter 200 may reach a longer distance than light emitted from the second light emitter 300 and may form a different beam pattern from light emitted from the second light emitter 300. When the same current is applied to the first light emitter 200 and the second light emitter 300, the amount of light of the first light emitter 200 may be formed to be greater than the amount of light of the second light emitter 300. The first light emitter 200 may be formed in a plurality, and arranged in the first region 111 while being spaced apart from each other in the first direction. An interval between the plurality of first light emitters 200 may be smaller than an interval between the plurality of pads 600 disposed adjacent to each other. Therefore, the turn-on/off regions of the light emitters may be controlled without electrically short-circuiting. The number of first light emitters 200 may be smaller than the number of second light emitters 300.

The size of each of the plurality of first light emitters 200 may be larger than the size of each of the plurality of second light emitters 300 in a plan view. However, the sum of the areas of the plurality of first light emitters 200 may be larger than twice of the sum of the areas of the plurality of second light emitters 300. A length c of the first light emitter 200 in the first direction may be smaller than a length d of the second light emitter 300 in the second direction. The length d of the first light emitter 200 in the second direction may be larger than the length a of the second light emitter 300 in the first direction. A ratio of the length d of the first light emitter 200 in the second direction to the length c of the first light emitter 200 in the first direction may be greater than a ratio of the length b of the second light emitter 300 in the second direction to the length a of the second light emitter 300 in the first direction. The size of the first light emitter 200 and the size of the second light emitter 300 may be as shown in the following Mathematical Expression 2.

$$\frac{b}{a} < \frac{d}{c} , b < d , a < d \qquad [ Mathematical Expression 2 ]$$

In the above Mathematical Expression 2, “a” denotes the length of the second light emitter 300 in the first direction, “b” denotes the length of the second light emitter 300 in the second direction, “c” denotes the length of the first light emitter 200 in the first direction, and “d” denotes the length of the first light emitter 200 in the second direction. Therefore, by disposing the plurality of light emitter regions with different ratios, it is possible to delicately control the distance and light intensity at which light is irradiated.

A contrast ratio of the light emitting device may be greater than or equal to about 150. The contrast ratio may be calculated by comparing the amounts of light of the plurality of first light emitters 200 adjacent to each other. For example, one of the plurality of first light emitters 200 adjacent to each other may be called a first adjacent light emitter P1 and the other may be called a second adjacent light emitter P2. When the first adjacent light emitter P1 is turned off and the second adjacent light emitter P2 is turned on, the contrast ratio of the light emitting device may be a value obtained by dividing luminance W2 measured from the second adjacent light emitter P2 by luminance W1 measured from the first adjacent light emitter P1. That is, W2/W1 may be greater than or equal to about 150.

Each of the plurality of first light emitters 200 may include a first light source 200a and a first wavelength conversion layer 200b as shown in FIG. 2. For example, the first light source 200a may be disposed on the light emitting substrate 110, and the first wavelength conversion layer 200b may be disposed on the first light source 200a.

The first light source 200a may generate light and be electrically connected to the light emitting substrate 110. A length of the first light source 200a in the first direction (horizontal direction in FIG. 2) may be smaller than a length of the first wavelength conversion layer 200b in the first direction. The first light source 200a may include a first conductive type semiconductor layer, an active layer, and a second conductive type semiconductor layer.

The first conductive type semiconductor layer may include a p-type dopant (e.g., Mg, Sr, or Ba). In other words, the first conductive type semiconductor layer may be a p-type semiconductor layer. However, this is merely an example, and the first conductive type semiconductor layer may also include an n-type dopant. In addition, the first conductive type semiconductor layer may be electrically connected to the light emitting substrate 110.

The active layer may be disposed on the first conductive type semiconductor layer. In other words, the active layer may be positioned between the first and second conductive type semiconductor layers. Furthermore, the first conductive type semiconductor layer and the active layer may form a mesa structure.

The second conductive type semiconductor layer may include an n-type dopant (e.g., Si, Ge, or Sn). Such a second conductive type semiconductor layer may be an n-type semiconductor layer. However, it is merely an example, and the second conductive type semiconductor layer may also include a p-type dopant. In addition, the second conductive type semiconductor layer may be electrically connected to the light emitting substrate 110.

The first wavelength conversion layer 200b may include a material or structure for diffusing light generated from the first light source 200a or for converting the wavelength of the light. The first wavelength conversion layer 200b may be disposed on the upper side of the first light source 200a. Additionally, the first wavelength conversion layer 200b may include a wavelength conversion material such as a phosphor, quantum dot (QD), or organic dye, which is capable of converting the wavelength of light emitted from the first light source 200a. For example, the wavelength conversion material may include a fluorescent substance capable of emitting one or more types of light among red, blue, and green light. In an embodiment, the first wavelength conversion layer 200b may be formed in the rectangular shape. When the first wavelength conversion layer 200b is formed in a rectangular shape, the thickness of the reflective layer 400 can be more easily controlled, and the formation of cracks in the reflective layer 400 can be prevented. In another embodiment, the first wavelength conversion layer 200b may have a shape in which the width thereof increases upward. By using such a first wavelength conversion layer 200b, light emitted from adjacent light emitters may overlap, thereby eliminating dark areas.

The plurality of first light emitters 200 may include the plurality of first upper devices 210 and the plurality of second upper devices 220.

The plurality of first upper devices 210 may be disposed between the plurality of second upper devices 220 and the plurality of second light emitters 300. In other words, the plurality of first upper devices 210 may be light emitters disposed between the plurality of second upper devices 220 and the plurality of second light emitters 300 among the plurality of first light emitters 200. The plurality of first upper devices 210 may be disposed in the first upper device region 111a. The number of first upper devices 210 may be greater than the number of second upper devices 220. In other words, with respect to the first direction (i.e., horizontal direction in FIGS. 4 and 5), a separation distance L1 from one side of the first upper device 210 disposed close to the side surface of the light emitting substrate 110 among the plurality of first upper devices 210 to the side surface of the light emitting substrate 110 may smaller than a separation distance L2 from one side of the second upper device 220 disposed close to the side surface of the light emitting substrate 110 among the plurality of second upper devices 220 to the side surface of the light emitting substrate 110.

The plurality of second upper devices 220 may be spaced apart from the plurality of second light emitters 300 than the plurality of first upper devices 210. In other words, the plurality of second upper devices 220 may be light emitters arranged in the first direction while being spaced apart from the plurality of second light emitters 300 than the plurality of first upper devices 210 among the plurality of first light emitters 200. The plurality of second upper devices 220 may be disposed in the second upper device region 111b. The number of second upper devices 220 may be smaller than the number of first upper devices 210.

The second light emitter 300 may be disposed on the light emitting substrate 110 to generate light forward. When the light emitting device 1 is mounted on the vehicle lamp, the second light emitter 300 may be disposed above the first light emitter 200, and when light transmits the lens of the vehicle lamp, the light may be refracted downward. The second light emitter 300 may form a different beam pattern from the light emitted from the first light emitter 200. The second light emitter 300 may be formed in a plurality, and arranged to be spaced apart from each other in the first direction. The plurality of second light emitters 300 may be disposed in the second region 112. An interval (i.e., gap) between the plurality of second light emitters 300 in the first and second directions may be smaller than the interval between the plurality of pads 600 disposed adjacent to each other. Therefore, the turn-on/off regions of the light emitters may be controlled without electrically short-circuiting.

A sum of the areas of the plurality of second light emitters 300 may be formed to be less than half a sum of the areas of the plurality of first light emitters 200.

The contrast ratio of each of the plurality of second light emitters 300 may be greater than or equal to about 150. The contrast ratio may be calculated by comparing the amounts of light of the plurality of second light emitters 300 adjacent to each other. For example, any one of the plurality of second light emitters 300 adjacent to each other may be called a third adjacent light emitter P3 and the other may be called a fourth adjacent light emitter P4. When the third adjacent light emitter P3 is turned off and the fourth adjacent light emitter P4 is turned on, the contrast ratio of the light emitting device may be a value obtained by dividing luminance W4 measured from above the fourth adjacent light emitter P4 by luminance W3 measured from above the third adjacent light emitter P3. That is, W4/W3 may be greater than or equal to about 150.

Each of the plurality of second light emitters 300 may include a second light source 300a and a second wavelength conversion layer 300b. The second light source 300a may be disposed on the light emitting substrate 110, and the second wavelength conversion layer 300b may be disposed on the second light source 300a.

The second light source 300a may generate light and may be electrically connected to the light emitting substrate 110. A length of the second light source 300a in the first direction (i.e., horizontal direction in FIG. 2) may be smaller than a length of the second wavelength conversion layer 300b in the first direction. The second light source 300a may include a first conductive type semiconductor layer, an active layer, and a second conductive type semiconductor layer.

The first conductive type semiconductor layer may include a p-type dopant (e.g., Mg, Sr, or Ba). In other words, the first conductive type semiconductor layer may be a p-type semiconductor layer. However, it is merely an example, and the first conductive type semiconductor layer may also include an n-type dopant. In addition, the first conductive type semiconductor layer may be electrically connected to the light emitting substrate 110. The active layer may be disposed on the first conductive type semiconductor layer.

In other words, the active layer may be positioned between the first and second conductive type semiconductor layers. Furthermore, the first conductive type semiconductor layer and the active layer may form a mesa structure.

The second conductive type semiconductor layer may include an n-type dopant (e.g., Si, Ge, or Sn). Such a second conductive type semiconductor layer may be an n-type semiconductor layer. However, this is merely an example, and the second conductive type semiconductor layer may also include a p-type dopant. Additionally, the second conductive type semiconductor layer may be electrically connected to the light emitting substrate 110.

The second wavelength conversion layer 300b may include a material or structure for diffusing light generated from the second light source 300a or for converting the wavelength of the light. The second wavelength conversion layer 300b may be disposed above the second light source 300a. In addition, the second wavelength conversion layer 300b may include a wavelength conversion material such as a phosphor, quantum dot (QD), or organic dye, which is capable of converting the wavelength of light emitted from the second light source 300a. For example, the wavelength conversion material may include a fluorescent substance capable of emitting one or more types of light among red, blue, and green. In an embodiment, the second wavelength conversion layer 300b may be formed in a rectangular shape. When the second wavelength conversion layer 300b is formed in the rectangular shape, the thickness of the reflective layer 400 can be more easily controlled, and the formation of cracks in the reflective layer 400 can be prevented. In another embodiment, the second wavelength conversion layer 300b may be formed in a shape in which the width thereof increases toward the top. With such a second wavelength conversion layer 300b, light emitted from adjacent light emitters may overlap, thereby eliminating dark areas.

The plurality of second light emitters 300 may include the plurality of first lower devices 310 and the plurality of second lower devices 320.

The plurality of first lower devices 310 may be spaced further apart from the first light emitter 200 than the plurality of second lower devices 320. The plurality of first lower devices 310 may be disposed in the first lower device region 112a. The plurality of second lower devices 320 may be disposed in the second lower device region 112b. In other words, the plurality of first lower devices 310 may be light emitters arranged on the upper side among the plurality of second light emitters 300.

The number of first lower devices 310 may be equal to the number of second lower devices 320, but is not limited thereto. Meanwhile, the plurality of first lower devices 310 and the plurality of second lower devices 320 may generate light to form a beam pattern with the same shape, but is not limited thereto, and may generate light to form beam patterns with different shapes.

The plurality of second lower devices 320 may be disposed between the plurality of first lower devices 310 and the first light emitter 200. The plurality of second lower devices 320 may be light emitters arranged between the plurality of first lower devices 310 and the first light emitter 200 among the plurality of second light emitters 300. The plurality of second lower devices 320 may be disposed in the second lower device region 112b. In other words, the plurality of second lower devices 320 may be disposed between the plurality of first lower devices 310 and the plurality of first upper devices 210.

Meanwhile, a diagonal length of the first light emitter 200 may be larger than a diagonal length of the second light emitter 300. The diagonal length of the first light emitter 200 may be expressed as in mathematical expression 3 below.

$${P}^{2} = {a}^{2} + {d}^{2} \qquad [ Mathematical Expression 3 ]$$

In the above mathematical expression 3, “p” may be a first vertex length p from a first vertex of any one of the plurality of first upper devices 210 disposed closest to the side surface of the light emitting substrate 110 to a second vertex of any one of the plurality of second lower devices 320 disposed closest to the side surface of the light emitting substrate 110. In addition, the first vertex length p from the first vertex to the second vertex may be a length for the longest interval among intervals between any one first upper device 210 where the first vertex is formed and the second lower device 320 where the second vertex is formed. In addition, “a” denotes the length a of the second light emitter 300 in the first direction, and “d” denotes the length d of the first light emitter 200 in the second direction. In other words, the first vertex length p may be formed to be larger than the diagonal length of the first light emitter 200, and the light emitting device 1 may form a high beam pattern, but is not limited thereto.

In addition, the first vertex length p may be expressed as in the following Mathematical Expression 4 below.

$${g}^{2} > {p}^{2} \qquad [ Mathematical Expression 4 ]$$

“g” may be a second vertex length g from the first vertex to a third vertex of any one of the plurality of second upper devices 220 disposed closest to the side surface of the light emitting substrate 110. In addition, the second vertex length g may be a length for the longest interval among intervals between any one first upper device 210 where the first vertex is formed and the second upper device 220 where the third vertex is formed. In other words, the first vertex length p may be formed to be smaller than the second vertex length g.

In addition, the first vertex length p and the first upper device 210 may form a predetermined first angle θ₁, and the second vertex length g and the second upper device 220 may form a predetermined second angle θ₂. The first angle θ₁ may be smaller than the second angle θ₂.

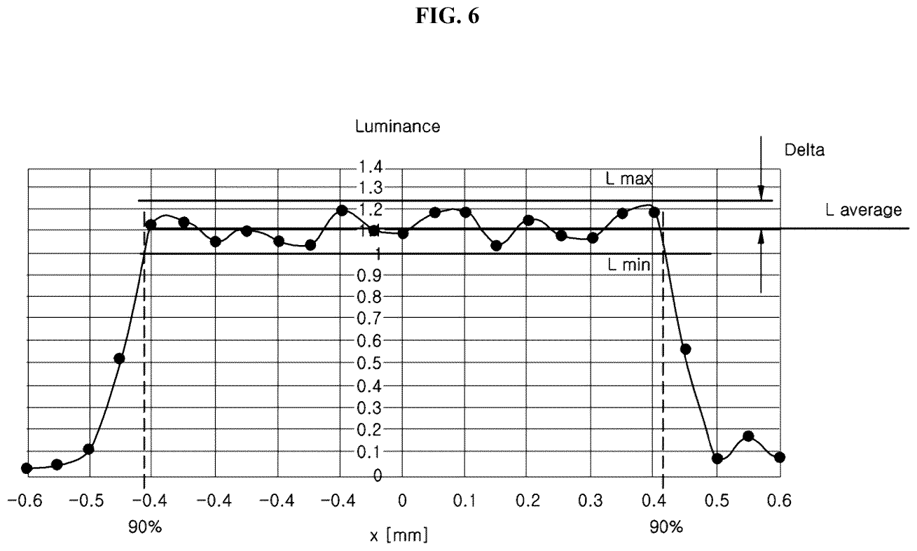

FIG. 6 is a schematic graph illustrating a deviation of luminance of the light emitting device according to one embodiment of the invention.

Referring further to FIG. 6, when light is emitted only from the plurality of first upper devices, or only from the plurality of second upper devices, or only from the first lower device, or only from the second lower device, the deviation of the luminance in the first direction may be formed to be about 30% or less.

The reflective layer 400 may be disposed on the surface of the light emitting substrate 110 and may reflect light generated from the plurality of first light emitters 200 and the plurality of second light emitters 300. The reflective layer 400 may reflect light generated from the plurality of first light emitters 200 and the plurality of second light emitters 300 to improve a surface light emission effect of the light emitting device 1. In a plan view, the reflective layer 400 may be disposed on the light emitting substrate 110 to cover circumferential surfaces of the plurality of first light emitters 200 and circumferential surfaces of the plurality of second light emitters 300. For example, the reflective layer 400 may be made of aluminum, silicon, carbon, etc.

Although not illustrated, the reflective layer 400 may be a mirror surrounding each of the plurality of first light emitters 200 and the plurality of second light emitters 300. The mirror may include a light reflective material. When the light emitters 200 and 300 include a semiconductor layer and a phosphor layer, the mirror may surround side surfaces of the semiconductor layer and the phosphor layer. The mirror surrounding each of the light emitters 200 and 300 may be spaced apart from each other with respect to a gap between adjacent mirrors. Accordingly, cold air may contact the mirror through the gap, and the light emitters 200 and 300 may be cooled to increase reliability. The mirror may have a wider upper region close to a light extraction surface than a lower region close to the light emitting substrate 110. In addition, since the mirror may have a step, a surface area that can in contact with air may increase, and a light extraction region may be sufficiently secured.

The heat sink 500 may support the pad substrate 120 and dissipate heat from the pad substrate 120. In addition, the heat sink 500 may dissipate heat generated from the plurality of first light emitters 200 and the plurality of second light emitters 300. The heat sink 500 may transmit heat to an outside, and lower a thermal resistance of the light emitting device 1 to improve the reliability of the light emitting device 1. In addition, the heat sink 500 may support the plurality of controllers 800.

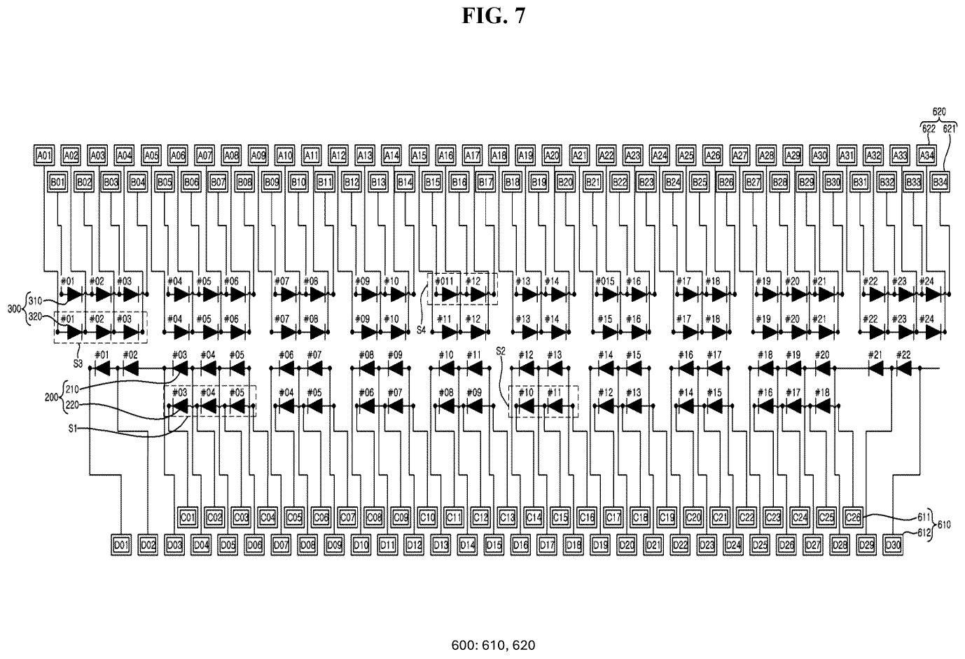

FIG. 7 is a schematic diagram illustrating an appearance in which the plurality of first light emitters and the plurality of second light emitters of the light emitting device according to one embodiment of the invention are electrically connected to the plurality of pads.

Referring further to FIG. 7, the pad 600 may be formed in a plurality and supported on the substrate unit 100, and may be electrically connected to the plurality of first light emitters 200 and the plurality of second light emitters 300. The plurality of pads 600 may include a plurality of first pads 610 and a plurality of second pads 620.

The plurality of first pads 610 may be electrically connected to the plurality of first light emitters 200. While the plurality of first pads 610 and the plurality of first light emitters 200 are electrically connected, the plurality of first light emitters 200 may be grouped into a plurality of upper groups. In other words, some of the plurality of first light emitters 200 may be grouped into a first upper group S1 while being electrically connected to some of the plurality of first pads 610, and others of the plurality of first light emitters 200 may be grouped into a second upper group S2 while being electrically connected to others of the plurality of first pads 610. The first upper group S1 may be a group adjacent to a side surface of the pad substrate 120 among the plurality of upper groups, and the second upper group S2 may be a group disposed adjacent to a center of the pad substrate 120 among the plurality of upper groups. For example, the first upper group S1 may be formed while pads C01, C02, C03, and C04 are electrically connected to the plurality of first light emitters 200 respectively. In addition, the second upper group S2 may be formed while pads C14, C15, and C16 are electrically connected to the plurality of first light emitters 200 respectively.

In this case, the number of first light emitters 200 included in the first upper group S1 may be greater than the number of first light emitters 200 included in the second upper group S2. For example, the number of first light emitters 200 included in the upper group may increase as the first light emitters 200 are spaced apart from the center of the pad substrate 120 in the plurality of upper groups. In addition, the number of first light emitters 200 included in one upper group may be smaller than the number of first pads 610 electrically connected to one upper group.

The plurality of first pads 610 may include a plurality of first upper pads 611 and a plurality of second upper pads 612.

The plurality of second upper pads 612 may be spaced apart from each other in the first direction (i.e., horizontal direction). The plurality of second upper pads 612 may be spaced further apart from the light emitting substrate 110 than the plurality of first upper pads 611. For example, the plurality of second upper pads 612 may include pads D01 to D30. The number of first upper pads 611 may be smaller than the plurality of second upper pads 612. At least some of the plurality of second upper pads 612 may overlap the plurality of first upper pads 611 disposed adjacent to each other when projected in the second direction (i.e., vertical direction). In addition, while the plurality of second upper pads 612 is electrically connected to the plurality of first upper devices 210, the first upper devices 210 may be grouped into the plurality of upper groups.

The plurality of first upper pads 611 may be spaced apart from each other in the first direction. The plurality of first upper pads 611 may be disposed between the plurality of second upper pads 612 and the light emitting substrate 110. For example, the plurality of first upper pads 611 may include pads C01 to C26. The plurality of first upper pads 611 may overlap the plurality of second upper pads 612 disposed adjacent to each other when projected in the second direction (i.e., vertical direction). In addition, while the plurality of first upper pads 611 are electrically connected to the plurality of second upper devices 220, the plurality of second upper devices 220 may be grouped into the plurality of upper groups.

The plurality of second pads 620 may be electrically connected to the plurality of second light emitters 300. While the plurality of second pads 620 and the plurality of second light emitters 300 are electrically connected, the plurality of second light emitters 300 may be grouped into a plurality of lower groups. In other words, some of the plurality of second light emitters 300 may be grouped into a first lower group S3 while being electrically connected to some of the plurality of second pads 620, and others of the plurality of second light emitters 300 may be grouped into a second lower group S4 while being electrically connected to others of the plurality of second pads 620. The first lower group S3 may be a group adjacent to the side surface of the pad substrate 120 among the plurality of lower groups, and the second lower group S4 may be a group disposed adjacent to the center of the pad substrate 120 among the plurality of lower groups. For example, the first lower group S3 may be formed while the second pads A01, A02, A03, and A04 are electrically connected to the plurality of the first lower devices 310 of the second light emitters 300. In addition, the second lower group S4 may be formed while second pads B15, B16, and B17 are electrically connected to the plurality of the second lower devices 320 of the second light emitters 300.

In this case, the number of second light emitters 300 included in the first lower group S3 may be greater than the number of first light emitters 200 included in the second upper group S2. For example, the number of second light emitters 300 included in the lower group may increase as the second light emitters 300 are spaced apart from the center of the pad substrate 120 in the plurality of lower groups. In addition, the number of second light emitters 300 included in one lower group may be smaller than the number of second pads 620 electrically connected to one lower group.

The plurality of second pads 620 may include a plurality of first lower pads 621 and a plurality of second lower pads 622.

The plurality of first lower pads 621 may be spaced apart from each other in the first direction (i.e., horizontal direction). The plurality of first lower pads 621 may be disposed between the plurality of second lower pads 622 and the light emitting substrate 110 in the first direction. For example, the plurality of first lower pads 621 may include pads B01 to B34. The number of first lower pads 621 may be equal to the number of second lower pads 622. The number of first lower pads 621 may be greater than the number of first upper pads 611 and the number of second upper pads 612. At least some of the plurality of first lower pads 621 may overlap the plurality of second lower pads 622 disposed adjacent to each other when projected in the second direction (i.e., vertical direction). In addition, while the plurality of first lower pads 621 is electrically connected to the plurality of first lower devices 310, the first lower devices 310 may be grouped into the plurality of lower groups.

The plurality of second lower pads 622 may be spaced apart from each other in the first direction (i.e., horizontal direction). The plurality of second lower pads 622 may be spaced further apart from the light emitting substrate 110 than the plurality of first lower pads 621 in the second direction (i.e., vertical direction). For example, the plurality of second lower pads 622 may include pads A01 to A34. At least some of the plurality of second lower pads 622 may overlap the plurality of first lower pads 621 disposed adjacent to each other when projected in the second direction (i.e., vertical direction). In addition, while the plurality of second lower pads 622 are electrically connected to the plurality of second lower devices 320, the plurality of second lower devices 320 may be grouped into the plurality of lower groups. The number of second lower pads 622 may be greater than the number of first upper pads 611 and the number of second upper pads 612.

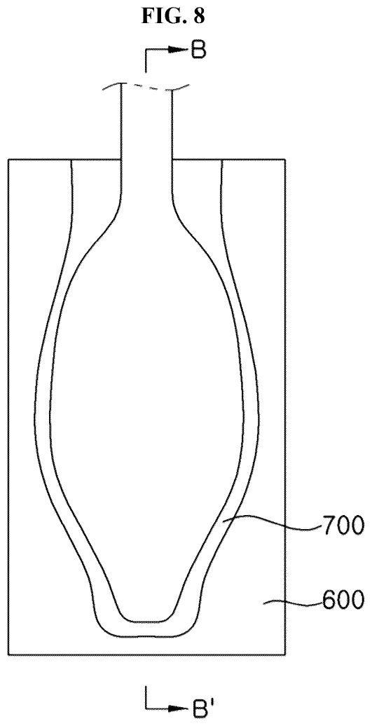

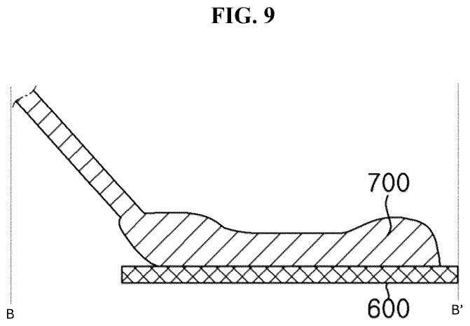

FIG. 8 is a schematic diagram illustrating an appearance in which a bonding part is disposed on the pad of the light emitting device according to one embodiment of the invention, and FIG. 9 is a schematic cross-sectional view of the bonding part of FIG. 8 taken along line B-B′.

Referring further to FIGS. 8 and 9, the bonding part 700 may be configured to electrically connect the plurality of controllers 800 and the plurality of pads 600 so that the plurality of first light emitters 200 and the plurality of second light emitters 300 are controlled. The bonding part 700 may be disposed on each of the plurality of pads 600 so that wires connect the plurality of controllers 800 and the plurality of pads 600, respectively. For example, the bonding part 700 may be wire-bonded to any one of the plurality of pads 600 so that any one of the plurality of pads 600 and any one of the plurality of controllers 800 are electrically connected to each other by the wire. The bonding part 700 may be formed to extend along a length direction of the pad 600. At least one of one side of the plurality of bonding parts 700 and the other side opposite to the one side of the plurality of bonding parts 700 may be formed to be convex upward and may be disposed above a center of the bonding part 700.

The controllers 800 may be formed in a plurality, and may be electrically connected to the plurality of pads 600 to control the plurality of first light emitters 200 and the plurality of second light emitters 300. The plurality of controllers 800 may independently control the plurality of upper groups and the plurality of lower groups. The plurality of controllers 800 may apply electricity to the plurality of first pads 610 so that light is generated in at least one of the plurality of upper groups. In addition, the plurality of controllers 800 may apply electricity to the plurality of second pads 620 so that light is generated in at least one of the plurality of lower groups. The plurality of controllers 800 may apply electricity to the plurality of first pads 610 so that the plurality of first light emitters 200 included in each of the plurality of upper groups sequentially emit light.

For example, when each of the plurality of first upper devices 210 included in the first upper group are called the first upper sub light emitter, the second upper sub light emitter, and the third upper sub light emitter, the first upper sub light emitter may emit light when electricity is applied to pads C01 and C02, the second upper sub light emitter may emit light when electricity is applied to pads C02 and C03, and the third upper sub light emitter may emit light when electricity is applied to pads C03 and C04. The controller 800 may apply electricity to pads C01 and C02, apply electricity to pads C02 and C03, and then apply electricity to pads C03 and C04 to emit light from the first upper group. When electricity is applied to the pads C01 and C02, electricity may not be applied to the pads C03 and C04. When electricity is applied to the pads C02 and C03, electricity may not be applied to the pads C01 and C04. When electricity is applied to the pads C03 and C04, electricity may not be applied to the pads C01 and C02.

In addition, the plurality of controllers 800 may apply electricity to the plurality of second pads 620 so that the plurality of second light emitters 300 included in each of the plurality of lower groups sequentially emit light.

For example, when each of the plurality of first lower devices 310 included in the first lower group are called the first lower sub light emitter, the second lower sub light emitter, and the third lower sub light emitter, the first lower sub light emitter may emit light when electricity is applied to pads B01 and B02, the second lower sub light emitter may emit light when electricity is applied to pads B02 and B03, and the third lower sub light emitter may emit light when electricity is applied to pads B03 and B04. The controller 800 may apply electricity to the pads B01 and B02, apply electricity to the pads B02 and B03, and then apply electricity to the pads B03 and B04 to emit light from the first lower group. When electricity is applied to the pads B01 and B02, electricity may not be applied to the pads B03 and B04. When electricity is applied to the pads B02 and B03, electricity may not be applied to the pads B01 and B04. In addition, when electricity is applied to the pads B03 and B04, electricity may not be applied to the pads B01 and B02.

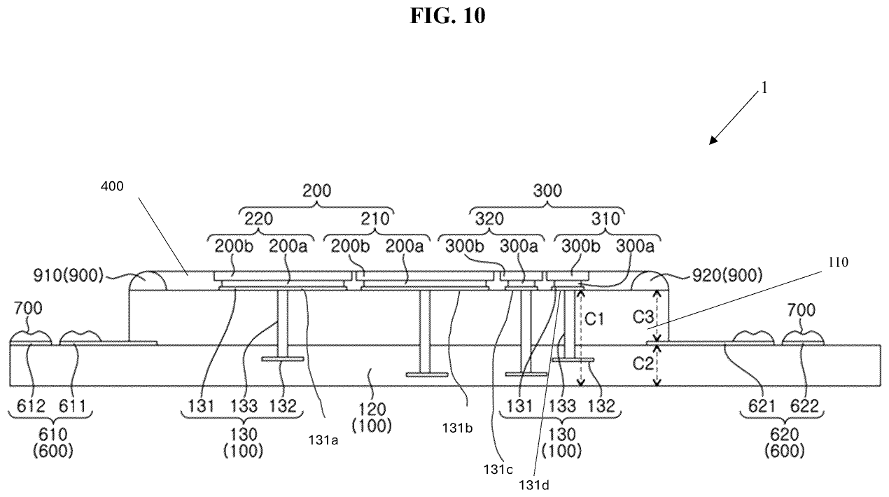

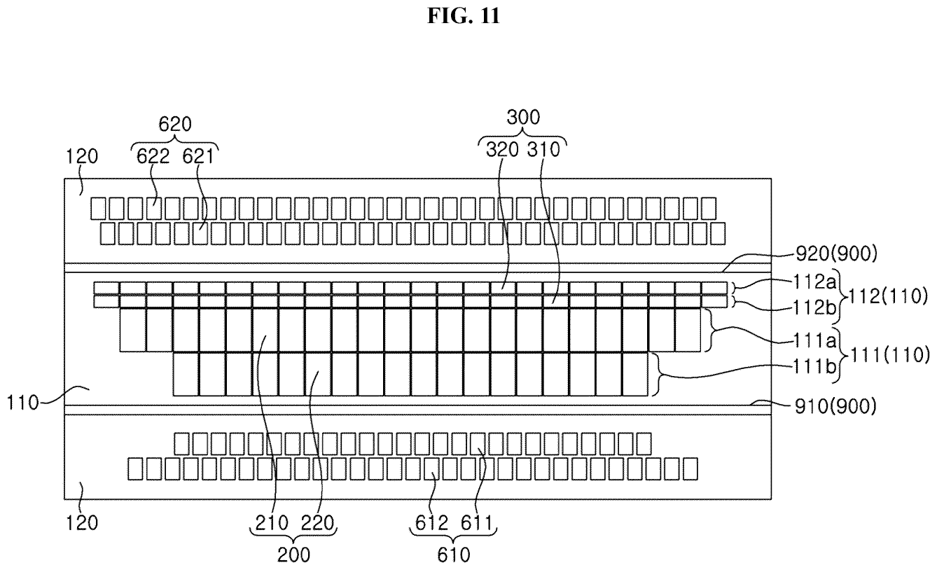

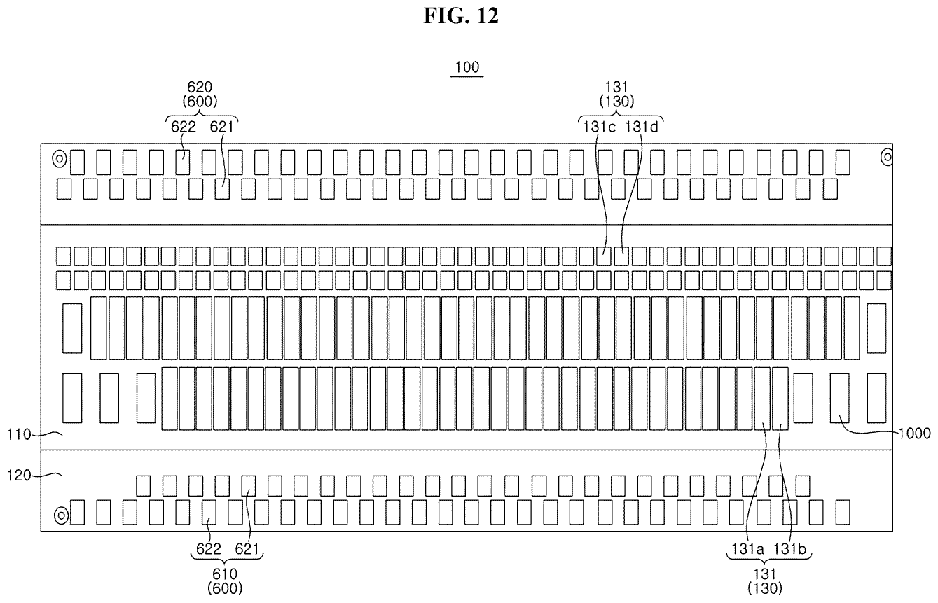

FIG. 10 is a schematic cross sectional view of a light emitting device according to another embodiment of the invention, and FIG. 11 is a schematic plan view showing a plurality of first light emitters, a plurality of second light emitters, and a plurality of pads of the light emitting device according to the second embodiment of the invention.

Hereinafter, the light emitting device 1 according to another embodiment will be described with reference to FIGS. 10 and 11. The explanation will focus on the differences, namely that a dam 900 is further included, and the substrate unit 100 further includes a substrate electrode 130.

The substrate electrode 130 may be formed in plurality and electrically connected to the first light emitter 200 or the second light emitter 300. The substrate electrodes 130 may extend upward from the pad substrate 120 to be electrically connected to the first light emitter 200 or the second light emitter 300. In other words, the substrate electrodes 130 may penetrate the light emitting substrate 110. Hereinafter, the substrate electrode 130 electrically connected to the first upper device 210 may be referred to as a first substrate electrode, and the substrate electrode 130 electrically connected to the second upper device 220 may be referred to as a second substrate electrode. Further, the substrate electrode 130 electrically connected to the first lower device 310 may be referred to as a third substrate electrode, and the substrate electrode 130 electrically connected to the second lower device 320 may be referred to as a fourth substrate electrode. A vertical length of the first substrate electrode and a vertical length of the fourth substrate electrode may be the same. A vertical length of the second substrate electrode and a vertical length of the third substrate electrode may be the same. A vertical length of the first substrate electrode and the fourth substrate electrode may be greater than a vertical length of the second substrate electrode and the third substrate electrode. Lower ends of the first and fourth substrate electrodes may be located lower than lower ends of the second and third substrate electrodes. Each of the plurality of substrate electrodes 130 may include an upper electrode 131, a lower electrode 132, and a connection electrode 133 which is disposed therebetween.

The upper electrode 131 may be disposed on the light emitting substrate 110 and may be electrically connected to the first light emitter 200 or the second light emitter 300. In other words, the upper electrode 131 may be positioned below the first light emitter 200 or the second light emitter 300. The upper electrode 131 may be disposed above the light emitting substrate 110 and may be exposed to an outside. In addition, the upper electrode 131 may be located above the pad 600. In other words, the pad 600 may be exposed to the outside at a position lower than the upper electrode 131. At least some of the upper electrodes 131 included in the plurality of substrate electrodes 130 may be disposed at the same height. Since the plurality of upper electrodes 131 is positioned at the same height, it may prevent any one of the first upper device 210, the second upper device 220, the first lower device 310, and the second lower device 320 from being positioned higher than another. Furthermore, since the plurality of upper electrodes 131 is disposed at the same height, the uniformity of the first and second light emitters may be improved. A separation distance C1 between a lower surface of the upper electrode 131 and a lower surface of the pad substrate 120 may be greater than a separation distance C2 between the lower surface of the pad substrate 120 and a lower surface of the pad 600. The first light emitter 200 and the second light emitter 300 may be positioned at a higher level than the upper electrode 131 due to the separation distance Cl between the lower surface of the upper electrode 131 and the lower surface of the pad substrate 120, thereby increasing the light extraction efficiency. In addition, since the separation distance C2 between the lower surface of the pad substrate 120 and the lower surface of the pad 600 is formed to be short, heat dissipation of the pad 600 may be increased and degradation of the pad 600 may be prevented by the heat sink 500 disposed on the lower surface of the pad substrate 120, and detachment of the bonding part 700 from the pad 600 due to thermal expansion and contraction may be avoided.

Further, the upper electrode 131 may include a first upper electrode 131a, a second upper electrode 131b, a third upper electrode 131c, and a fourth upper electrode 131d.1

The first upper electrode 131a may be an electrode electrically connected to the first conductive type semiconductor layer of the first light emitter 200. The second upper electrode 131b may be an electrode electrically connected to the second conductive type semiconductor layer of the first light emitter 200. The first upper electrode 131a and the second upper electrode 131b may be formed in plurality and disposed in the first region 111. The plurality of first upper electrodes 131a and second upper electrodes 131b may be arranged alternately in the first direction within the first region 111. In other words, the first upper electrode 131a and the second upper electrode 131b may be arranged in a direction perpendicular to a long axis direction of the first light emitter 200 within the first region 111. A size of the first upper electrode 131a and the second upper electrode 131b may be formed larger than a size of the third upper electrode 131c and the fourth upper electrode 131d. A length of the first upper electrode 131a and the second upper electrode 131b in the first direction (i.e., horizontal direction) may be larger than a length of the third upper electrode 131c and the fourth upper electrode 131d in the first direction. A length of the first upper electrode 131a and the second upper electrode 131b in the second direction (i.e., vertical direction) may be the same as a length of the third upper electrode 131c and the fourth upper electrode 131d in the second direction.

The third upper electrode 131c may be an electrode electrically connected to the first conductive type semiconductor layer of the second light emitter 300. The fourth upper electrode 131d may be an electrode electrically connected to the second conductive type semiconductor layer of the second light emitter 300. The third upper electrode 131c and the fourth upper electrode 131d may be formed in plurality and disposed in the second region 112. The plurality of third upper electrodes 131c and the plurality of fourth upper electrodes 131d may be arranged alternately in the first direction within the second region 112. In other words, the third upper electrode 131c and the fourth upper electrode 131d may be arranged in a direction parallel to the long axis direction of the second light emitter 300 within the second region 112.

By means of the first upper electrode 131a, the second upper electrode 131b, the third upper electrode 131c, and the fourth upper electrode 131d, the degree of freedom in arranging the light source can be increased according to the desired circuit configuration.

The lower electrode 132 may be disposed on the substrate electrode 130. The lower electrode 132 may be positioned below the upper electrode 131. Further, among the plurality of lower electrodes 132, those closer to the dam 900 may be positioned higher in the first direction (i.e., vertical direction). The lower electrode 132 of the first substrate electrode and the lower electrode 132 of the fourth substrate electrode may be positioned lower than the lower electrode 132 of the second substrate electrode and the lower electrode 132 of the third substrate electrode. In other words, the lower electrode 132 of the second substrate electrode and the lower electrode 132 of the third substrate electrode, which are positioned closer to the dam 900, may be disposed higher than the lower electrode 132 of the first substrate electrode and the lower electrode 132 of the fourth substrate electrode. Since at least some of the plurality of lower electrodes 132 may be arranged at different heights, interference between the lower electrodes 132 can be minimized, and short circuits can be prevented.

Additionally, a separation distance between the lower electrode 132 of the first substrate electrode and the upper electrode 131 of the first substrate electrode in the second direction (i.e., vertical direction) may be the same as a separation distance between the lower electrode 132 of the fourth substrate electrode and the upper electrode 131 of the fourth substrate electrode in the second direction (i.e., vertical direction). A separation distance between the lower electrode 132 of the second substrate electrode and the upper electrode 131 of the second substrate electrode in the second direction (i.e., vertical direction) may be the same as a separation distance between the lower electrode 132 of the third substrate electrode and the upper electrode 131 of the third substrate electrode in the second direction (i.e., vertical direction). Furthermore, the lower electrode 132 may be positioned below the pad 600.

The connection electrode 133 may extend in the vertical direction to electrically connect the upper electrode 131 and the lower electrode 132. The connection electrode 133 may penetrate the light emitting substrate 110. A vertical length of the connection electrode 133 of the first substrate electrode and a vertical length of the connection electrode 133 of the fourth substrate electrode may be the same. A vertical length of the connection electrode 133 of the second substrate electrode and a vertical length of the connection electrode 133 of the third substrate electrode may be the same. A vertical length of the connection electrode 133 of the first substrate electrode and the connection electrode 133 of the fourth substrate electrode may be greater than a vertical length of the connection electrode 133 of the second substrate electrode and the connection electrode 133 of the third substrate electrode. Due to the connection electrode 133, more metal can be placed at the center of the light emitting substrate 110 than at its edges, thereby increasing the heat dissipation efficiency at the center of the light emitting substrate 110 and enhancing the core strength of the light emitting substrate 110.

Meanwhile, the light emitting substrate 110 and the pad substrate 120 of the substrate unit 100 may be formed integrally, but are not limited thereto. In other words, the light emitting substrate 110 and the pad substrate 120 may be formed as separate components and bonded together. Additionally, in a plan view, a long axis of the light emitting substrate 110 and a long axis of the pad substrate 120 may be the same. A short axis of the light emitting substrate 110 may be smaller than a short axis of the pad substrate 120.

The dam 900 may be disposed on the upper side of the light emitting substrate 110. The dam 900 may prevent the reflective layer 400 from detaching from the light emitting substrate 110. The dam 900 may be disposed at the edge of the light emitting substrate 110. The dam 900 may extend along the long axis of the light emitting substrate 110. The dam 900 may be formed of the same material as the reflective layer 400 to ensure a strong bond with the reflective layer 400, but it is not limited thereto. In other words, the dam 900 and the reflective layer 400 may include different materials to prevent cracks due to thermal stress by having different thermal properties. The dam 900 may be formed such that a width thereof narrows toward the top. For example, an upper surface of the dam 900 may be formed as a curved surface. A height of an upper end of the dam 900 may be equal to or lower than a height of an upper surface of the first light emitter 200 or the second light emitter 300. The curved surface of the dam 900 can enhance the light reflection effect at the dam 900 and disperse thermal stress. The dam 900 may include a first dam 910 and a second dam 920.

The first dam 910, in a plan view, may be disposed between the first light emitter 200 and the first pad 610. The first dam 910 may prevent the reflective layer 400 from spilling toward the first pad 610. The second dam 920, in a plan view, may be disposed between the second light emitter 300 and the second pad 620. The second dam 920 may prevent the reflective layer 400 from spilling toward the second pad 620. The first dam 910 and the second dam 920 may be arranged parallel to each other. The first dam 910 and the second dam 920 may prevent the light emitting substrate 110 from bending along a extension direction of the first dam 910 and the second dam 920.

The pad 600 may include an embedded region disposed between the light emitting substrate 110 and the pad substrate 120. In other words, at least a portion of the first upper pad 611 or the second lower pad 622 may be embedded between the light emitting substrate 110 and the pad substrate 120. The embedded region, when viewed in the vertical direction, may be arranged to overlap with the first dam 910 or the second dam 920. The embedded region can prevent the pad 600 from detaching from the substrate unit 100. Further, the separation distance C3 from an upper surface of the pad 600 to the upper surface of the light emitting substrate 110 may be greater than the separation distance C2 from the lower surface of the pad substrate 120 to the lower surface of the pad 600. Since the embedded region can be pressed toward the pad substrate 120 by the light emitting substrate 110, the bonding strength between the pad 600 and the substrate unit 100 can be increased. The upper surface of the pad 600 may be positioned higher than the lower electrode 132.

FIG. 12 is a schematic plan view of a substrate unit of a light emitting device according to another embodiment of the invention.

Hereinafter, with reference to FIG. 12, the light emitting device 1 according to another embodiment will be described. The difference lies in the inclusion of a dummy pad 1000, and this difference will be primarily explained.

The dummy pad 1000 may be disposed outside the plurality of first light emitters 200. In other words, in a plan view, the dummy pad 1000 may be disposed on the light emitting substrate 110 so as to be located outside the plurality of upper electrodes 131. Further, the dummy pad 1000 may be formed in plurality. When one of the plurality of dummy pads 1000 is projected in the second direction onto the upper electrode 131, a portion thereof may overlap the first upper electrode 131a, and another portion may overlap the second upper electrode 131b. Due to the dummy pad 1000, the heat dissipation efficiency of the light emitting device 1 can be increased.

A length of the dummy pad 1000 in the first direction (i.e., horizontal direction) may be equal to or greater than the length of the first upper electrode 131a and the second upper electrode 131b in the first direction (i.e., horizontal direction). Furthermore, a length of the dummy pad 1000 in the first direction (i.e., horizontal direction) may be equal to or greater than the length of the third upper electrode 131c and the fourth upper electrode 131d in the first direction (i.e., horizontal direction). A length of the dummy pad 1000 in the second direction (i.e., vertical direction) may be smaller than the length of the first upper electrode 131a and the second upper electrode 131b in the second direction (i.e., vertical direction). Furthermore, a length of the dummy pad 1000 in the second direction (i.e., vertical direction) may be larger than the length of the the third upper electrode 131c and the fourth upper electrode 131d in the second direction (i.e., vertical direction).

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A light emitting device, comprising:
a substrate unit that includes a light emitting substrate;
a plurality of first light emitters that are arranged in a first direction on the light emitting substrate to generate light; and
a plurality of second light emitters that are arranged in the first direction on the light emitting substrate to generate the light,
wherein the plurality of first light emitters and the plurality of second light emitters are disposed in a second direction perpendicular to the first direction, and
wherein a size of each of the plurality of first light emitters is larger than a size of each of the plurality of second light emitters in a plan view.

2. The light emitting device of claim 1, wherein a ratio of a length of the second light emitter in the second direction to a length of the second light emitter in the first direction is smaller than a ratio of a length of the first light emitter in the second direction to a length of the first light emitter in the first direction.

3. The light emitting device of claim 1, wherein a sum of areas of the plurality of first light emitters is larger than twice of a sum of areas of the plurality of second light emitters.

4. The light emitting device of claim 1, wherein a length of the first light emitter in the first direction is smaller than a length of the second light emitter in the second direction, and
wherein a length of the first light emitter in the second direction is larger than a length of the second light emitter in the first direction.

5. The light emitting device of claim 1, further comprising:
a reflective layer that is disposed on the light emitting substrate and reflects the light generated from the plurality of first light emitters and the plurality of second light emitters.

6. The light emitting device of claim 5, wherein the reflective layer covers circumferential surfaces of the plurality of first light emitters and circumferential surfaces of the plurality of second light emitters.

7. A light emitting device, comprising:
substrate unit including a light emitting substrate;
a plurality of first light emitters that are arranged and supported in a first direction on the light emitting substrate to generate light; and
a plurality of second light emitters that are arranged and supported in the first direction on the light emitting substrate to generate the light,
wherein the light emitting substrate includes:
a first region in which the plurality of first light emitters are arranged; and
a second region in which the plurality of second light emitters are arranged, and
wherein a length of the first region in the first direction is smaller than a length of the second region in the first direction.

8. The light emitting device of claim 7, wherein a separation distance from one side of the first region to one side of the light emitting substrate is larger than a separation distance from one side of the second region to one side of the light emitting substrate.

9. The light emitting device of claim 7, wherein the plurality of first light emitters includes:
a plurality of first upper devices; and
a plurality of second upper devices that are spaced further apart from the second light emitter than the plurality of first upper devices,
wherein the first region includes:
a first upper device region in which the plurality of first upper devices are arranged; and
a second upper device region in which the plurality of second upper devices are arranged, and
wherein a length of the first upper device region in the first direction is larger than a length of the second upper device region in the first direction.

10. The light emitting device of claim 9, wherein the second upper device region is disposed on an inner side of the first upper device region when projected toward the first upper device region.

11. A light emitting device, comprising:
a substrate unit;
a plurality of first light emitters that are arranged and supported on the substrate unit in a first direction to generate light;
a plurality of second light emitters that are arranged and supported on the substrate unit in the first direction to generate the light; and
a plurality of pads that are arranged and supported on the substrate unit in the first direction and are electrically connected to the plurality of first light emitters and the plurality of second light emitters,
wherein the substrate unit includes:
a light emitting substrate that supports the plurality of first light emitters and the second light emitters; and
a pad substrate that supports the plurality of pads and the light emitting substrate, and
wherein the light emitting substrate protrudes upward from the pad substrate so that a surface of the light emitting substrate is disposed above a surface of the pad substrate.

12. The light emitting device of claim 11, wherein a length of the light emitting substrate in a vertical direction is larger than a length of the pad substrate in the vertical direction.

13. The light emitting device of claim 11, wherein the plurality of pads include:
a plurality of first pads that are electrically connected to the plurality of first light emitters while being spaced apart from each other; and
a plurality of second pads that are supported on the pad substrate while being spaced apart from each other, and electrically connected to the plurality of second light emitters, and
wherein the light emitting substrate is disposed between the plurality of first pads and the plurality of second pads.

14. The light emitting device of claim 11, wherein a number of second pads is different from a number of first pads.

15. The light emitting device of claim 11, wherein a separation distance between the plurality of pads is larger than a separation distance between the plurality of first light emitters and a separation distance between the plurality of second light emitters.

16. The light emitting device of claim 13, wherein the plurality of first pads include:
a plurality of first upper pads that are spaced apart from each other in the first direction; and
a plurality of second upper pads that are spaced apart from each other in the first direction, but spaced further apart from the light emitting substrate than the plurality of first upper pads, and
wherein at least some of the plurality of first upper pads are disposed to overlap the plurality of second upper pads disposed adjacent to each other when projected in a second direction perpendicular to the first direction.

17. The light emitting device of claim 13, wherein the plurality of second pads include:
a plurality of first lower pads that are spaced apart from each other in the first direction; and
a plurality of second lower pads that are spaced apart from each other in the first direction, and disposed between the plurality of first lower pads and the light emitting substrate, and
wherein at least some of the plurality of second lower pads are disposed to overlap the plurality of first lower pads disposed adjacent to each other when projected in a second direction perpendicular to the first direction.

18. The light emitting device of claim 11, further comprising:
a heat sink that supports the pad substrate and dissipates heat from the pad substrate.

19. The light emitting device of claim 13, further comprising:
a plurality of controllers that are electrically connected to the plurality of pads for controlling the plurality of first light emitters and the plurality of second light emitters; and
a plurality of bonding parts that electrically connect the plurality of controllers and the plurality of pads.

20. The light emitting device of claim 19, wherein at least one of one side of the plurality of bonding parts and an other side opposite the one side of the plurality of bonding parts is formed to be convex upward.
